(19) United States
(12) Patent Application Publication
(10) Pub. No.: US 2023/0358925 A1
(43) Pub. Date: Nov. 9, 2023

(54) DIE INCLUDING OPTICAL ELEMENTS

(71) Applicant: VIAVI SOLUTIONS INC., San Jose, CA (US)

(72) Inventors: Riberet ALMEIDA, Rochester, NY (US); Tasso R.M. SALES, Rochester, NY (US); Jaroslaw ZIEBA, Santa Rosa, CA (US); Kangning LIANG, Santa Rosa, CA (US)

(73) Assignee: VIAVI SOLUTIONS INC., San Jose, CA (US)

(21) Appl. No.: 17/737,865

(22) Filed: May 5, 2022

(51) Int. Cl. G02B 5/02; G03F 7/00; G02B 5/00

(52) U.S. Cl. CPC G02B 5/003; G02B 5/0215; G03F 7/0002; G02B 1/002

(57) ABSTRACT

A die including a substrate; and a plurality of optical elements on a portion of a surface of the substrate; in which each optical element, of the plurality of optical elements, includes at least one optical function; and in which each optical element, of the plurality of optical elements, is separated one from another by a barrier material is disclosed. A wafer including a plurality of dies; a method of making a wafer; and a method of making a die are also disclosed.

### FIELD OF THE INVENTION

The present disclosure generally relates to a die including a substrate; and a plurality of optical elements on a portion of a surface of the substrate; in which each optical element, of the plurality of optical elements, includes at least one optical function; and in which each optical element, of the plurality of optical elements, is separated one from another b∨y a barrier material. A wafer including a plurality of dies; a method of making a wafer; and a method of making a die are also disclosed.

### BACKGROUND OF THE INVENTION

There are several benefits associated with making light-shaping optical elements, such as light diffusers and other diffractive optics, in such a way that they incorporate various spatially defined features obtained by implementing a patterning process. This can be relevant to a group of light-shaping optical elements called polymer-on-glass (PoG) diffusers. One example, of such a feature, is separation of the polymer layer forming, the light diffusing element, into discrete regions surrounded by a bare glass region or areas where additional optically or non-optically relevant functions can be realized. The simplest example, of such a non-optical function provided by the bare glass region, is creating glass-only dicing streets around the PoG layer of the optical diffuser. The benefits of implementing this patterning feature is described below:

Light-shaping optical elements such as diffusers, diffractive elements, etc. are often made by applying and properly structuring UV curable polymeric materials on glass substrates. Regardless of the type of UV curable polymeric materials, such as cationic-cure epoxies, free radical cure acrylates or other UV curable systems, it is challenging to make light-shaping optical elements that can pass high reliability standards imposed by an end user. In particular, when the light-shaping optical element is made in a wafer format and then subjected to dicing into small single dies with sizes 3 ×2 mm or smaller, various defects form along the dicing edge and in corners of those dies. During the thermal cycling test, that involves up to a 1,000 -40° C./+85° C. cycles, these defects contribute to delamination of the polymeric material from a glass substrate or to cohesive failure of glass.

What is needed is a wafer including a plurality of dies separated one from another by a street so that the wafer can be diced along the street with reduced or zero damage to the individual dies. The dies can have a plurality of optical elements separated one from another by a barrier material in order to inhibit or reduce cross-talk between optical elements.

### BRIEF DESCRIPTION OF THE DRAWINGS

Features of the present disclosure are illustrated by way of example and not limited in the following figure(s), in which like numerals indicate like elements, in which:

FIG. 1A illustrates a die according to an aspect of the invention;

FIG. 1B is a cross-section of the die of FIG. 1A according to an aspect of the invention;

FIG. 1C is a cross-section of the die of FIG. 1A according to another aspect of the invention;

FIG. 1D is a cross-section of the die of FIG. 1A according to another aspect of the invention;

FIG. 2 is a die including a dicing street, according to an aspect of the invention;

FIG. 3 is a wafer according to an aspect of the invention; and

FIGS. 4A-4E illustrate steps in a method of making a wafer and a die.

### SUMMARY OF THE INVENTION

In an aspect, there is disclosed a die including a substrate; and a plurality of optical elements on a portion of a surface of the substrate; in which each optical element, of the plurality of optical elements, includes at least one optical function; and in which each optical element, of the plurality of optical elements, is separated one from another by a barrier material.

In another aspect, there is disclosed a wafer comprising a plurality of dies separated one from another by a street.

In another aspect, there is disclosed a method of making a wafer including dispensing an elastomeric material onto a substrate; contacting the elastomeric material with a soft mold tool including a photomask; and curing portions of the elastomeric material.

In another aspect, there is disclosed a method of making a die comprising dicing a wafer along the streets to separate a die from the plurality of dies.

Additional features and advantages of various embodiments will be set forth, in part, in the description that follows, and will, in part, be apparent from the description, or can be learned by the practice of various embodiments. The objectives and other advantages of various embodiments will be realized and attained by means of the elements and combinations particularly pointed out in the description herein.

### DETAILED DESCRIPTION OF THE INVENTION

For simplicity and illustrative purposes, the present disclosure is described by referring mainly to an example thereof. In the following description, numerous specific details are set forth in order to provide a thorough understanding of the present disclosure. It will be readily apparent however, that the present disclosure may be practiced without limitation to these specific details. In other instances, some methods and structures have not been described in detail so as not to unnecessarily obscure the present disclosure.

Additionally, the elements depicted in the accompanying figures may include additional components and some of the components described in those figures may be removed and/or modified without departing from scopes of the present disclosure. Further, the elements depicted in the figures may not be drawn to scale and thus, the elements may have sizes and/or configurations that differ from those shown in the figures.

It is to be understood that both the foregoing general description and the following detailed description are exemplary and explanatory only, and are intended to provide an explanation of various embodiments of the present teachings. Additionally, any reference to “top”, “bottom”, “right”, and/or “left” are intended to provide relative physical relationships and is not intended to be limiting.

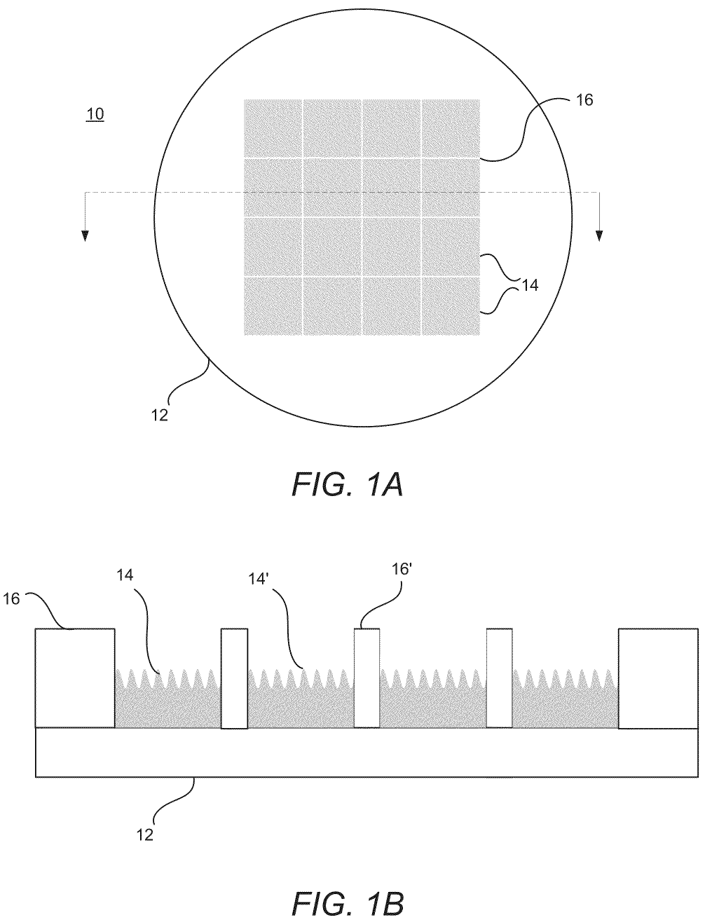

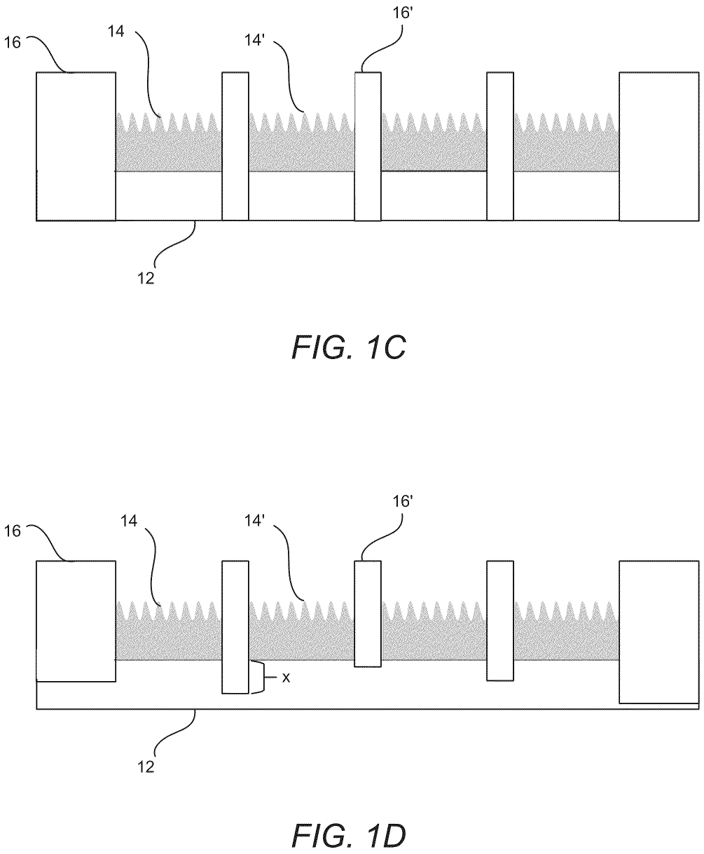

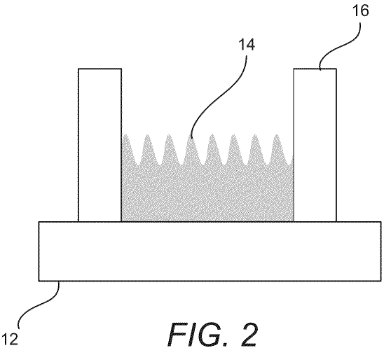

In its broad and varied embodiments, disclosed herein is a die 10 comprising a substrate 12; and a plurality of optical elements 14 on a portion of a surface of the substrate 12; wherein each optical element 14, of the plurality of optical elements 14, includes at least one optical function; and wherein each optical element 14, of the plurality of optical elements 14, is separated one from another by a barrier material 16, as shown in FIGS. 1A-1D and 2. The barrier material 16, 16′ can reduce the cross-talk between the plurality of optical elements 14.

FIG. 1A illustrates a die 10 including a substrate 12 with a plurality of optical elements 16 arranged in an array on the substrate 12. The optical elements 14 are separated from each other by a barrier material 16. The substrate 12, which is described more fully below, can be in any shape, size, and/or configuration, such as a circle. The plurality of optical elements 14, which are described more fully below, can be arranged in any configuration, such as a 4x4 array.

FIGS. 1B-1D illustrate a cross-section of a die 10 with a barrier material 16 that can separate one optical element 14 from another optical element 14′. The barrier material 16 can be a plurality of barrier material 16, as shown in FIGS. 1B-1D. The barrier material 16 can have a first surface, such as a bottom surface, that is flush (e.g., forms a continuous plane) with a bottom surface of the elastomeric material 14, and/or a top surface of the substrate 12 as shown in FIG. 1B. In particular, the barrier material 16 can include a top surface that extends beyond a height of the optical element 14, and a bottom surface that interfaces with a top surface of the substrate 12.

In an aspect, the barrier material 16 can include a bottom surface that extends through the substrate 12, as shown in FIG. 1C. In this manner, the bottom surface of the barrier material 16 is flush with (shares a same plane) a bottom surface of the substrate 12. The barrier material 16 can be embedded within a portion of the substrate. For example, the barrier material 16 can be embedded a pre-determined distance, x, into the substrate 12, as shown in FIG. 1D. The pre-determined distance of the embedding can vary in order to allow for accessing a specific optical function implemented in the isolated optical element. Selected optical elements can operate with different wavelengths of light and variation in the depth of the barrier material can be expected to help with integrating these functions. In an aspect, the barrier material 16 can be a plurality of barrier materials 16, 16′, and each barrier material 16 can be embedded a different pre-determined distance, x, into the substrate 12. The barrier material 16, 16′ can include a top surface that is in a common plane with each other, so long as the top surface extends above a top surface of the optical element 14, 14′.

The barrier material 16 can be different sizes and configurations, for example, depending upon the function within the die 10. Barrier material 16 that can be located at an outer portion of the die 10 can be present in a larger size and/or configuration as compared to a barrier material 16 located at an inner portion of the die 10. As shown in FIGS. 1B-D, the barrier material 16 at an outer portion of the die 10 can be a wide rectangle shape as compared to the barrier material 16′ at an inner portion of the die 10 can be a narrow rectangle shape.

The barrier material 16, 16′ and the optical element 14, 14′ can be positioned to form a design or pattern. The design or pattern can enable specific architecture of the optical element created within a sing die. In an aspect, the pattern can allow for replication of light-shaping optical elements with shapes that are not rectangular. For example, various benefits can be achieved from including round-shaped optical elements within the die that cannot be achieved with rectangular-shaped optical elements.

The barrier material 16 can be chosen from optically opaque materials and optically absorbing materials. The optically opaque materials can be a metallic based pigment including a metallic core and dielectric shell that can provide a particular degree of light absorption. In some cases, the metallic-based pigment can represent particles of various metals with a passivation layer. The shape and size of those particles can be selected to properly adjust their optical and electrical properties. Non-limiting examples of metals that can be used in the metallic-based pigment can include copper, iron, silver, and nickel. The metallic-based pigments may, by design, offer reflectance in selected parts of the spectrum.

The dielectric shell can be a single layer of dielectric material or a plurality of layers of dielectric material, such as a dielectric stack. The dielectric material can be a high refractive index material (e.g., greater than 1.65) or a low refractive index material (e.g., less than or equal to 1.65). The dielectric shell can be a layer on a surface of the metal core, or can be an encapsulating layer (e.g., partially or completely).

In another aspect, the optically opaque material can be an electroformed structure. For example, the optically opaque material can be deposited as a layer of metal using an electro-chemical deposition technique. In an aspect, the optically opaque material can be nickel. The optically opaque material can be a metal including, but not limited to, alkali metals, alkaline metals, transition metals, post-transition metals, lanthanides, actinides, and ferromagnetic metals.

The optically absorbing material can include both selective absorbing materials and nonselective absorbing materials. For example, the optically absorbing material can be formed of nonselective absorbing metallic materials deposited to a thickness at which it is at least partially absorbing, or semi-opaque. An example of a non-selective absorbing material can be a gray metal, such as chrome or nickel. An example of a selective absorbing material can be copper or gold. In an aspect, the absorbing material can be chromium. Non-limiting examples of suitable absorber materials include metallic absorbers such as chromium, aluminum, silver, nickel, palladium, platinum, titanium, vanadium, cobalt, iron, tin, tungsten, molybdenum, rhodium, niobium, carbon, graphite, silicon, geranium, cermet and various combinations, mixtures, compounds, or alloys of the above absorber materials.

Examples of suitable alloys of the above absorber materials can include Inconel (Ni—Cr—Fe), stainless steels, Hastalloys (Ni—Mo—Fe; Ni—Mo— F—Cr; Ni—Si—Cu) and titanium-based alloys, such as titanium mixed with carbon (Ti/C), titanium mixed with tungsten (Ti/W), titanium mixed with niobium (Ti/Nb), and titanium mixed with silicon (Ti/Si), and combinations thereof. Other examples of suitable compounds for the optically absorbing material include titanium-based compounds such as titanium silicide (TiSi₂), titanium boride (TiB₂), and combinations thereof. Alternatively, the optically absorbing material can be composed of a titanium-based alloy disposed in a matrix of Ti, or can be composed of Ti disposed in a matrix of a titanium-based alloy.

As discussed above, the die 10 can include a substrate 12. The substrate 12 can be any material that can receive one or more optical elements 14. In an aspect, as shown in FIGS. 1A and 2, a portion of the surface of the substrate 12 can be free of the plurality of optical elements 14 and/or the barrier material 16. An interface between the substrate 12 and the optical elements 14 can be continuous. For example, an interface between the substrate 12 and the optical element 14 and/or barrier material 16 can be free of chips or cracks. The chips and cracks, which would provide a discontinuous interface between the substrate 12 and the optical element 14 and/or barrier material 16, can be caused by dicing. In this manner, a cross-section of the interface can be free of damage.

In an aspect, the substrate 12 can be a transparent material. Non-limiting examples of suitable substrate materials include glass, fused silica, soda lime and polymers, such as polycarbonate, polymethylmethacrylate, polyethylene terephthalate, polyethylene, amorphous copolyester, polyvinyl chloride; liquid silicon rubber, cyclic olefin copolymers, ionomer resin, transparent polypropylene, fluorinated ethylene propylene, styrene methyl methacrylate, styrene acrylonitrile resin, polystyrene, and methyl methacrylate acrylonitrile butadiene styrene. In an aspect, the substrate 12 can be a clear material including fused silica, soda lime, and combinations thereof.

The substrate 12 can be present at a thickness ranging from about 0.05 mm to about 6.35 mm, for example, from about 0.1 mm to about 5 mm, and, as a further example, from about 0.15 mm to about 1.0 mm.

The die 10 can include a plurality of optical elements 14, 14′. Each optical element of the plurality of optical elements 14, 14′ can be formed of any curable polymer. Non-limiting examples of a suitable polymer include thermoplastics, such as polyesters, polyolefins, polycarbonates, polyamides, polyimides, polyurethanes, acrylics, acrylates, polyvinylesters, polyethers, polythiols, silicones, fluorocarbons, and various co-polymers thereof, thermosets, such as epoxies, polyurethanes, acrylates, melamine formaldehyde, urea formaldehyde, and phenol formaldehyde; and energy curable materials, such as acrylates, epoxies, vinyls, vinyl esters, styrenes, and silanes. Additional polymers include, but are not limited to, silanes, siloxanes, titanates, zirconates, aluminates, silicates, phosphazanes, polyborazylenes, and polythiazyls.

The polymer chains can be crosslinked using a polymerization technique, and then cured. Non-limiting examples of a polymerization technique include photoinduced polymerization, such as free radical polymerization, spectrally sensitized photoinduced free radical polymerization, photoinduced cationic polymerization, spectrally sensitized photoinduced cationic polymerization, and photoinduced cycloaddition; electron beam induced polymerization, such as electron beam induced free radical polymerization, electron beam induced cationic polymerization, and electron beam induced cycloaddition; and thermally induced polymerization, such as thermally induced cationic polymerization. In an aspect, the polymer can be cross-linked and/or cured using a technique such as a non-radical cure system, an ultraviolet light, a visible light, an infrared light, and/or an electron beam.

The optical elements 14, 14′ can be in a form of a layer with a first surface that is planar and a second surface, opposite the first surface, that is planar or patterned. The optical elements 14, 14′ can be present at differing thicknesses along a length of a layer. Additionally, if a portion of the optical elements 14, 14′ is patterned, then that patterned portion can include differing thicknesses.

The elastomeric material can be present in a composition with a cross-linking agent. Non-limiting examples of a suitable cross-linking agent include organic peroxides, amines, amides, silanes, epoxies, free radical monomers, UV cure monomers, isocyanates, and the like. The cross-linking agent can be present in a composition with the elastomeric material in any amount to assist in cross-linking and/or curing the elastomeric material. As will be discussed in more detail herein, the elastomeric material when used in a method of making a wafer 18 can be applied as a liquid, and can be cured.

Each optical element of the plurality of optical elements 14, 14′ can have at least one surface chosen from flat, curved, and textured. In an aspect, at least one surface of each optical element 14, 14′ can include nanoparticles, nanorods, nanospears, and combinations thereof, which can provide antifungal, antibacterial, and antiviral properties to the optical elements 14, 14′. They can be made of materials such as copper, silver, phosphomolybdate, graphene, reduced graphene oxide, polyoxometalates, and metal oxides such as copper oxide or zinc oxide.

At least one surface of each optical element 14, 14′ can be a diffusing surface. At least one surface of each optical element 14, 14′ can be surface engineered into an optical metasurface.

Each optical element of the plurality of optical elements 18 can have a coating on at least a portion of a surface of each optical element 14, 14′. The coating can be chosen from antireflective, reflective, transparent electrically conductive, oleophobic, hydrophobic, superhydrophobic, smudge resistant, cleanable or self-cleanable, antifungal, antibacterial, antiviral, and combinations thereof. The coating can be an optical coating, or a functional coating, for example, providing radiation and/or heat management. In an aspect, an optical element 14, 14′ can have an integrated filter design providing functions, such as notch, bandpass, or visible color functions. For example, an optical notch filter can provide performance for LIDAR windows for use in autonomous cars, drones, etc.

The optical element 14, 14′ can include a high refractive index material, for example, having a refractive index greater than about 1.8. The high refractive index material can be a hydride, a nitride, a carbide, or a metal oxide. Non-limiting examples of a high refractive index material include zinc sulfide (ZnS), zinc oxide (ZnO), zirconium oxide (ZrO₂), titanium dioxide (TiO₂), carbon (C), indium oxide (In₂O₃), indium-tin-oxide (ITO), tantalum pentoxide (Ta₂O₅), ceric oxide (CeO₂), yttrium oxide (Y₂O₃), europium oxide (EU₂O₃), iron oxides such as (II)diiron(III) oxide (Fe₃O₄) and ferric oxide (Fe₂O₃), hafnium nitride (HfN), hafnium carbide (HfC), hafnium oxide (HfO₂), lanthanum oxide (La₂O₃), magnesium oxide (MgO), neodymium oxide (Nd₂O₃), praseodymium oxide (Pr₆O₁₁), samarium oxide (Sm₂O₃), antimony trioxide (Sb₂O₃), silicon carbide (SiC), silicon nitride (Si₃N₄), silicon monoxide (SiO), silicon hydride (SiH), selenium trioxide (Se₂O₃), tin oxide (SnO₂), tungsten trioxide (WO₃), combinations thereof, and the like. In an aspect, the optical element 14, 14′ can include silicon hydride.

The optical element 14, 14′ can include a high refractive index material and one or more other materials. The high refractive index material can be present in the optical element 14, 14′ in a major amount, i.e., 50% or greater, relative to the total amount of the optical element 14, 14′. The other material can be present in the optical element 14, 14′ in a minor amount, i.e., less than 50%, relative to the total amount of the optical element 14, 14′. In an aspect, the optical element 14, 14′ can include a high refractive index material and trace amounts of various elements, and/or compounds. As an example, the optical element 14, 14′ can include silicon hydride and at least one other material chosen from nitrogen, oxygen, silicon hydroxide, niobium pentoxide (Nb₂O₅), niobium titanium oxide (NbTiOₓ) wherein x is an integer from 1 to 6, and SiC:H. In particular, the optical element 14, 14′ can include silicon hydride, nitrogen, and oxygen. The optical element 14, 14′ can include silicon hydride and trace amounts of one or more other materials chosen from nitrogen, oxygen, silicon hydroxide, and silicon carbide doped with hydrogen (SiC:H).

The optical element 14, 14′ of the die 10 can provide at least one optical function chosen from a diffusing element, a collimating lens, a light modulator, and a micro-lens array. The optical element 14 can provide proper shaping of a laser beam, and can provide power distribution, power intensity and potential cross-talk of various wavelengths within a bundle of laser beams coming from various laser sources.

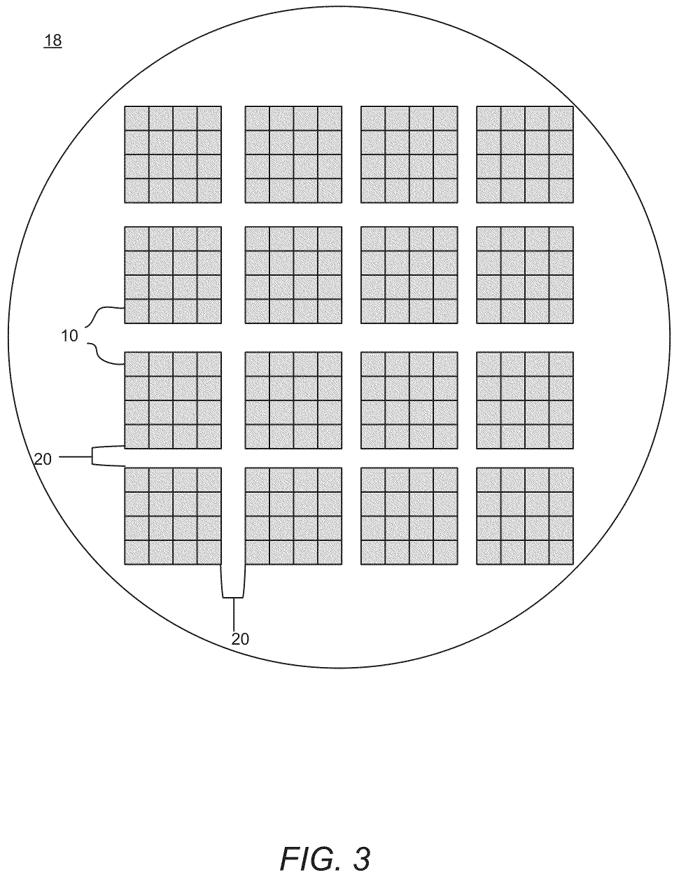

As shown in FIG. 3, there is also disclosed a wafer 18 comprising a plurality of dies 10 separated one from another by a street 20. The wafer 18 can include a plurality of dies 10 arranged in a variety of configurations, such as an array of 4 × 4 dies. The street 20 can be substantially devoid of elastomeric material. For example, street 20 can include less than 50% by volume of elastomeric material as compared to an optical element. In another example, the street 20 can be completely void of elastomeric material. In this manner, the street 20 can be a layer of substrate, such as glass. In another aspect, the street 20 can be a layer of substrate interfacing with a layer of barrier material, which would separate the plurality of dies 10.

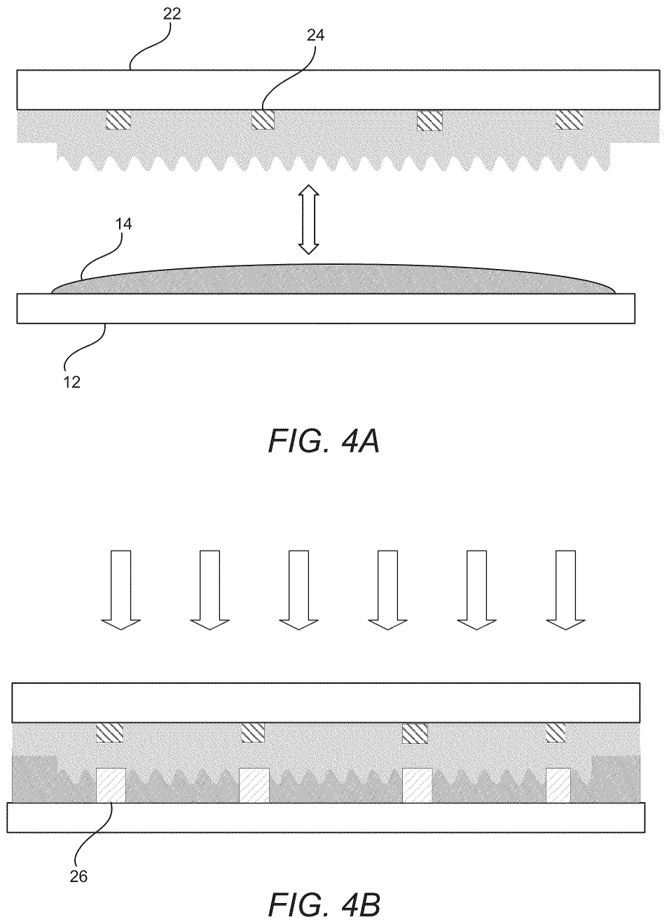

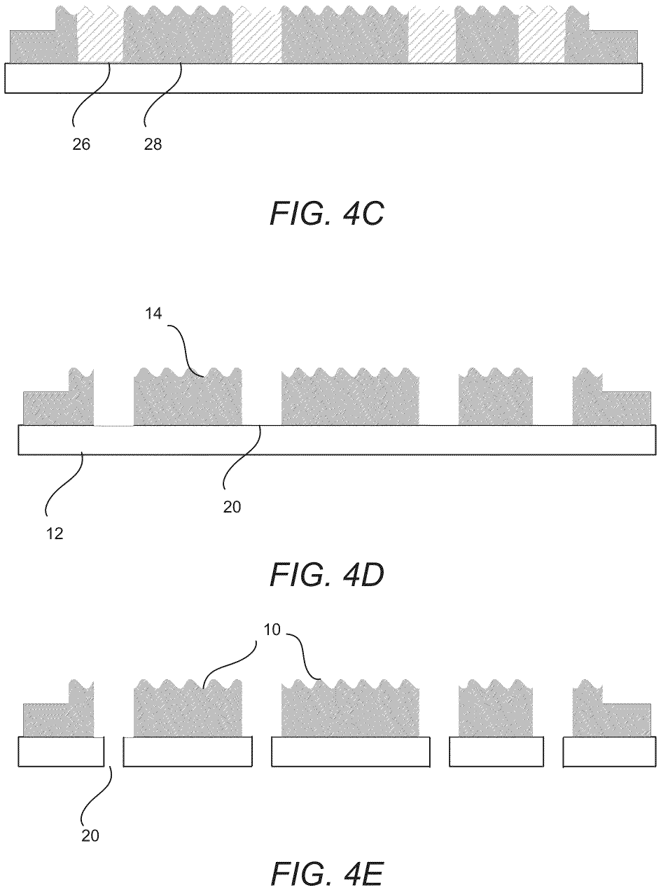

As shown in FIGS. 4A-4B, a method of making a wafer 18 can comprise dispensing an elastomeric material 14 onto a substrate 12; contacting the elastomeric material 14 with a soft mold tool 22 including a photomask; and curing portions of the elastomeric material. The soft mold tool 22 can include a photomask 24 in pre-determined locations to inhibit the curing of the elastomeric material in those locations 26. Curing of the elastomeric material can be accomplished with any technique, such as, application of a collimated light source or a diffusing light source.

As shown in FIG. 4C, the method can also include, after curing, separating the soft mold tool 22 from the cured portions 28 of the elastomeric material and the uncured portions 26 of the elastomeric material.

As shown in FIG. 4D, the method can also include, after the step of separating, developing off uncured portions of the elastomeric material to form streets 20. The step of developing off can include applying an organic solution, such as, to the uncured portions of the elastomeric material. In this manner, on one or more portions of a surface of the substrate 12 there can be cured elastomeric material. There can also be one or more portions of the surface of the substrate 12 that are void of any elastomeric material, e.g., cured or uncured elastomeric material. By removing or developing off the uncured portions of the elastomeric material prior to dicing of the wafer, it is believed that this would reduce or inhibit the likelihood of damage, such as cracks or chips, from developing at an interface between the substrate 12 and the optical element 14.

The method can further include applying a barrier material 16, such as an optically opaque material, in the streets 20. The barrier material 16 can be applied using photolithography, electrochemical, or printing techniques.

As shown in FIG. 4E, a method of making a die 10 can include dicing a wafer 18 along the streets 20 to separate a die from the plurality of dies.

From the foregoing description, those skilled in the art can appreciate that the present teachings can be implemented in a variety of forms. Therefore, while these teachings have been described in connection with particular embodiments and examples thereof, the true scope of the present teachings should not be so limited. Various changes and modifications can be made without departing from the scope of the teachings herein.

This scope disclosure is to be broadly construed. It is intended that this disclosure disclose equivalents, means, systems and methods to achieve the devices, activities and mechanical actions disclosed herein. For each device, article, method, mean, mechanical element or mechanism disclosed, it is intended that this disclosure also encompass in its disclosure and teaches equivalents, means, systems and methods for practicing the many aspects, mechanisms and devices disclosed herein. The claims of this application are likewise to be broadly construed. The description of the inventions herein in their many embodiments is merely exemplary in nature and, thus, variations that do not depart from the gist of the invention are intended to be within the scope of the invention. Such variations are not to be regarded as a departure from the spirit and scope of the invention.

What is claimed is:

1. A die comprising:
a substrate; and
a plurality of optical elements on a portion of a surface of the substrate;
wherein each optical element, of the plurality of optical elements, includes at least one optical function; and
wherein each optical element, of the plurality of optical elements, is separated one from another by a barrier material.

2. The die of claim 1, wherein the barrier material is chosen from an optically opaque material and an optically absorbing material.

3. The die of claim 1, wherein the barrier material includes a top surface that extends beyond a height of the optical element, and a bottom surface that interfaces with a top surface of the substrate.

4. The die of claim 1, wherein the barrier material includes a bottom surface that extends to a bottom surface of the substrate.

5. The die of claim 1, wherein the barrier material is embedded into the substrate a pre-determined distance.

6. The die of claim 1, wherein the barrier material is a plurality of separate barrier materials, and each barrier material is embedded a different pre-determined distance into the substrate.

7. The die of claim 2, wherein the optically opaque material is a metallic based pigment.

8. The die of claim 2, wherein the optically opaque material is an electroformed structure.

9. The die of claim 1, wherein a portion of the surface of the substrate is free of the plurality of optical elements.

10. The die of claim 1, wherein an interface between the substrate and the optical element is continuous.

11. The die of claim 10, wherein a cross-section of the interface is free of damage.

12. The die of claim 1, wherein the at least one optical function is chosen from a diffusing element, a collimating lens, a light modulator, and a micro-lens array.

13. A wafer comprising:
a plurality of dies separated one from another by a street, wherein each die is recited in claim 1.

14. A method of making a wafer, comprising:
dispensing an elastomeric material onto a substrate;
contacting the elastomeric material with a soft mold including a photomask; and
curing portions of the elastomeric material.

15. The method of claim 14, further comprising, after curing, separating the soft mold tool from the cured elastomeric material.

16. The method of claim 15, further comprising, after separating, developing off uncured portions of the elastomeric material to form streets.

17. The method of claim 16, wherein the streets are substantially void of elastomeric material.

18. The method of claim 16, wherein developing includes applying an organic solution.

19. The method of claim 16, further comprising, applying a barrier material in the streets.

20. A method of making a die comprising:
dicing a wafer according to claim 13 along the streets to separate a die from the plurality of dies.
